(19) United States
(12) Patent Application Publication
(10) Pub. No.: US 2026/0367147 A1
(43) Pub. Date: Nov. 19, 2026

(54) INTERNAL TEMPERATURE MONITORING FOR CIRCUIT TESTING

(71) Applicant: NVIDIA Corporation, Santa Clara, CA (US)

(72) Inventors: Nithin Anil Valentine, San Jose, CA (US); Mahmut Yilmaz, Los Altos Hills, CA (US); Vikrant Bharadwaj, Sunnyvale, CA (US); Lordson Yue, Los Altos, CA (US); Berra Kara, San Francisco, CA (US); Kevin Kuo, Los Altos, CA (US); Shantanu Sarangi, Saratoga, CA (US); Rohit Suhas Kurane, San Jose, CA (US); Ramakrishnan Ganesh, Milpitas, CA (US)

(21) Appl. No.: 19/206,233

(22) Filed: May 13, 2025

(51) Int. Cl. G01R 31/317; G01K 1/02

(52) U.S. Cl. CPC G01R 31/31725; G01K 1/026

(57) ABSTRACT

Systems and methods for monitoring and controlling integrated circuit testing enable safe and reliable structural testing of integrated circuits. At least one embodiment relates to an integrated circuit having multiple integrated temperature sensors thermally coupled to logic blocks and an integrated test controller that controls structural testing based on temperature measurements from the sensors.

### BACKGROUND

Structural testing plays an integral role in validating integrated circuit functionality and reliability. During structural testing, test patterns exercise various logic blocks within an integrated circuit to verify proper operation and identify potential defects. These test patterns typically generate significant switching activity within the circuit, with toggle rates ranging from 30-50% of the circuit nodes. Testing can occur at multiple stages of a product lifecycle, including manufacturing validation, system integration, and field deployment in data centers and other production environments.

Temperature monitoring and control systems help maintain safe operating conditions during these intensive test procedures. Test equipment interfaces with the integrated circuit through standardized protocols to deliver test patterns and collect results, while cooling systems regulate device temperature to prevent thermal damage.

### BRIEF DESCRIPTION OF THE SEVERAL VIEWS OF THE DRAWINGS

In the drawings, which are not necessarily drawn to scale, like numerals may describe similar components in different views. To easily identify the discussion of any particular element or act, the most significant digit or digits in a reference number refer to the figure number in which that element is first introduced. The drawings illustrate examples. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. At least one non-limiting example embodiment is illustrated in the figures of the accompanying drawings.

FIG. 1 is a block diagram illustrating a system for temperature monitoring and control during structural testing of an integrated circuit, according to at least one embodiment.

FIG. 2 is a detailed block diagram illustrating internal components and interconnections of an integrated circuit with temperature monitoring capabilities during structural testing, according to at least one embodiment.

FIG. 3 illustrates a method for performing structural testing of an integrated circuit, according to at least one embodiment.

FIG. 4 is a diagrammatic representation of a machine in the form of a computer system within which a set of instructions is stored that may be executed to cause the machine to perform one or more operations, according to at least one embodiment.

### DETAILED DESCRIPTION

Structural testing plays an integral role in validating integrated circuit functionality and reliability across multiple stages of product lifecycle, including manufacturing validation, system integration, and field deployment in data centers and other production environments. At least one embodiment addresses challenges in temperature monitoring and control during these intensive test procedures.

During structural testing, test patterns exercise various logic blocks within an integrated circuit, generating significant switching activity with toggle rates ranging from 30-50% of circuit nodes. This high level of activity creates substantial power consumption and heat generation that can potentially damage both the integrated circuit and testing equipment.

When temperature monitoring is inadequate during testing, both the device under test (DUT) and the testing equipment risk being damaged by high temperatures that are not properly monitored or remediated. Because of this risk, some testing protocols avoid testing the device for robustness to high temperatures; in such conservative testing protocols, defects that only manifest at high temperatures may be missed, resulting in reduced performance in deployed chips. Current approaches rely on external temperature monitoring through single temperature diode sensors placed at chip peripheries. A temperature protection pad on a production board, coupled to the sensor, can be used to trigger external intervention to shut down and reboot the chip and power supply rails when temperature thresholds are exceeded. This external monitoring approach provides limited temperature coverage, because the components involved in measurement may themselves be under test, and the temperature diode sensors at chip edges do not provide accurate or timely representation of temperatures across the entire chip, leading to slow coolant system responses that risk thermal runaway conditions and potential damage to testing equipment.

In at least one embodiment, an integrated circuit (IC) incorporates multiple integrated temperature sensors distributed across various logic blocks within the IC die. Temperature sensing monitors within or otherwise thermally coupled to each logic block sequentially monitor these integrated temperature sensors, providing comprehensive temperature data coverage across the integrated circuit.

A system controller receives temperature measurements from sensor bridges that interface with the temperature sensing monitors and generates temperature data from the received measurements. In at least one embodiment, a temperature data processor processes the temperature data received from the system controller to generate temperature analysis data, which an integrated test controller uses to control structural testing operations. The temperature analysis data can include analysis of the temperature data over time in order to detect predetermined temperature events and/or log temperature trends in the various logic blocks.

The integrated test controller can implement various control responses based on temperature conditions. These responses include temporarily pausing testing until temperature decreases, stopping testing entirely, or modifying test execution parameters. In at least one embodiment, the integrated test controller can generate temperature log data that captures detailed temperature measurements and testing events. In at least one embodiment, the temperature analysis data generated by the temperature data processor can include an interrupt signal generated in response to detecting a predetermined temperature event, and the integrated test controller can pause or halt the structural testing in response to receiving the interrupt signal. Thus, at least one embodiment described herein can provide temperature measurements for different portions of the logic blocks during various structural testing scenarios, including in-system testing, system level testing, burn-in testing, and automatic test equipment testing.

A communication link can be included in the IC to enable interaction with systems external to the IC. Through this link, the integrated circuit can provide coolant control data to a coolant system. This allows for dynamic adjustment of cooling parameters based on precise internal temperature measurements. In at least one embodiment, the communication link provides external test equipment data to external test equipment used during the structural testing. In at least one embodiment, the communication link is a Peripheral Component Interconnect Express (PCIe) or Inter-Integrated Circuit (I²C) link.

In at least one embodiment, the IC can use one or more types of temperature sensors, such as bipolar junction transistor (BJT)-based sensors, diode-based sensors, or ring oscillator-based sensors.

The temperature data collected during testing can be used for multiple purposes beyond immediate control of the structural testing process. At least one embodiment generates temperature analysis data, which can include temperature statistics for each monitored portion of each logic block, such as minimum, maximum, and average temperature values per sensor. This data can assist in analyzing test failures, identifying temperature-dependent defects, and/or optimizing test patterns to reduce power consumption in subsequent testing. In at least one embodiment, all or part of the temperature analysis data can be stored in an external memory for concurrent and/or subsequent use.

In at least one embodiment, various testing platforms and scenarios can be supported, from manufacturing validation to in-field testing in datacenter environments. When deployed in production environments, the temperature monitoring capabilities of the IC can potentially assist in preventing disruptive full-system reboots that would otherwise require reloading drivers and applications across multiple processing units.

Through integration of temperature monitoring, test control, and external communication capabilities, at least one embodiment can enable safe and reliable structural testing while maintaining detailed temperature data for analysis and optimization, thereby potentially addressing thermal management challenges across the complete product lifecycle, from initial manufacturing to field deployment.

Thus, at least one embodiment described herein seeks to provide a technical solution to one or more example technical problems.

First, structural testing lacks effective internal temperature monitoring capabilities during testing operations. During structural testing, test patterns generate 30-50% toggle activity within logic blocks of the IC device under test (DUT), creating substantial power consumption and heat generation. At least one embodiment may address this by implementing multiple integrated temperature sensors distributed across logic blocks, with dedicated temperature sensing monitors that sequentially monitor these sensors. Temperature data can be processed through sensor bridges and a system controller to enable comprehensive temperature monitoring during testing.

Second, existing temperature monitoring systems provide limited coverage and slow response times. Current solutions rely on single external temperature diode sensors placed at chip peripheries, which cannot accurately represent temperatures across the entire chip. At least one embodiment may implement a hierarchical monitoring system wherein temperature sensing monitors within each logic block connect to multiple internal sensors, feeding temperature measurements through sensor bridges to a system controller. This can enable rapid detection of temperature events across all IC regions.

Third, structural testing systems lack direct temperature-based control mechanisms. Current systems can only regulate coolant flow based on external sensor data, using a single temperature sensor coupled externally along a periphery of an IC chip, with no ability to modify test execution based on temperature conditions. At least one embodiment may implement an integrated test controller that receives temperature analysis data from a temperature data processor. This can enable immediate test control responses, including pausing testing until temperature decreases, stopping testing entirely, and/or modifying test execution parameters.

Fourth, high-temperature burn-in testing faces reliability challenges due to thermal management limitations. Current coolant systems respond slowly to temperature changes, risking thermal runaway and equipment damage. At least one embodiment may provide temperature feedback through a communication link to external cooling systems, enabling dynamic coolant adjustment based on detailed and timely internal temperature data. The system can also generate detailed temperature statistics for analysis and optimization of cooling, testing, and/or other operations.

Fifth, datacenter testing environments lack efficient temperature management solutions. Current approaches require full system reboots when temperature issues occur, forcing reload of drivers and applications across multiple ICs, such as multiple GPUs or other processors. At least one embodiment may enable internal test control responses without system reboots, while maintaining detailed temperature log data in system memory for analysis. At least one embodiment of the temperature monitoring and testing control architectures described herein may support various testing scenarios, including in-system testing, system level testing, burn-in testing, and/or automatic test equipment testing.

For example, in a datacenter environment using multiple graphical processing units (GPUs) or other processors, when a temperature-related shutdown occurs in one GPU in a node or cluster, current approaches to temperature management may trigger a full system reboot that requires reloading GPU drivers and software applications across all GPUs in the node. This reboot process can involve powering down the chip and power supply rails, reinitializing the hardware, reloading the operating system drivers that enable GPU functionality, and restarting any applications that were running on the GPUs.

In contrast, at least one embodiment described herein is configured to pause or end testing based on temperature data without requiring a system-wide reboot. When a thermal interrupt is generated, an integrated test controller can either temporarily pause testing until temperatures decrease or stop the current test entirely, while maintaining system power and driver states. This allows testing to resume quickly after a pause, without the time-consuming process of reloading drivers and applications across multiple GPUs. In at least one embodiment, a testing pause maintains the system state and allows testing to continue from the point of interruption once temperatures return to acceptable levels. Even when testing must be stopped completely, the stop process can be configured to avoid triggering the cascading reboot of all GPUs in the node that occurs in some existing external temperature protection mechanisms.

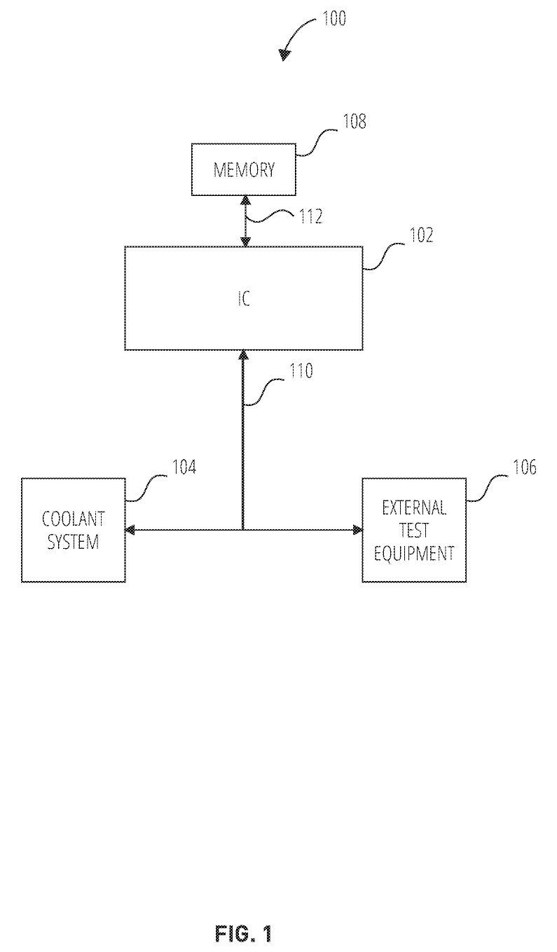

FIG. 1 is a block diagram illustrating a system 100 for temperature monitoring and control during structural testing of an integrated circuit, according to at least one embodiment.

The system 100 includes an integrated circuit (IC) 102 that interfaces with multiple external components through various data connections. A memory 108 connects to IC 102 through a memory interface 112, enabling storage and retrieval of test data and temperature measurements.

The IC 102 interfaces with two other external components through a communication link 110: a coolant system 104 and external test equipment 106. The communication link 110 can be implemented using standard interfaces such as PCIe or I²C, enabling bidirectional data transfer between the IC and these external components.

The coolant system 104 receives temperature feedback data from the IC 102 through the communication link 110, allowing dynamic adjustment of cooling parameters based on internal temperature measurements. The coolant system 104 can include several interconnected components (not shown) that work together to maintain appropriate temperature conditions. In at least one embodiment, a primary cooling unit circulates liquid coolant, such as a water and glycol mixture, through a closed-loop system that interfaces with thermal interface components thermally coupled to the IC 102. Heat transfer occurs through these thermal interface components, which can include cold plates or heat sinks in direct contact with the IC package. The coolant system 104 can incorporate control mechanisms that regulate coolant flow rates and maintain consistent temperatures based on feedback received through the communication link 110. During burn-in testing, the coolant system 104 can function as a burn-in coolant that actively responds to temperature data to prevent thermal runaway conditions that could damage testing equipment or the IC 102 itself. The coolant system 104 can potentially support various testing scenarios, including in-system testing, system level testing, burn-in testing, and automatic test equipment testing.

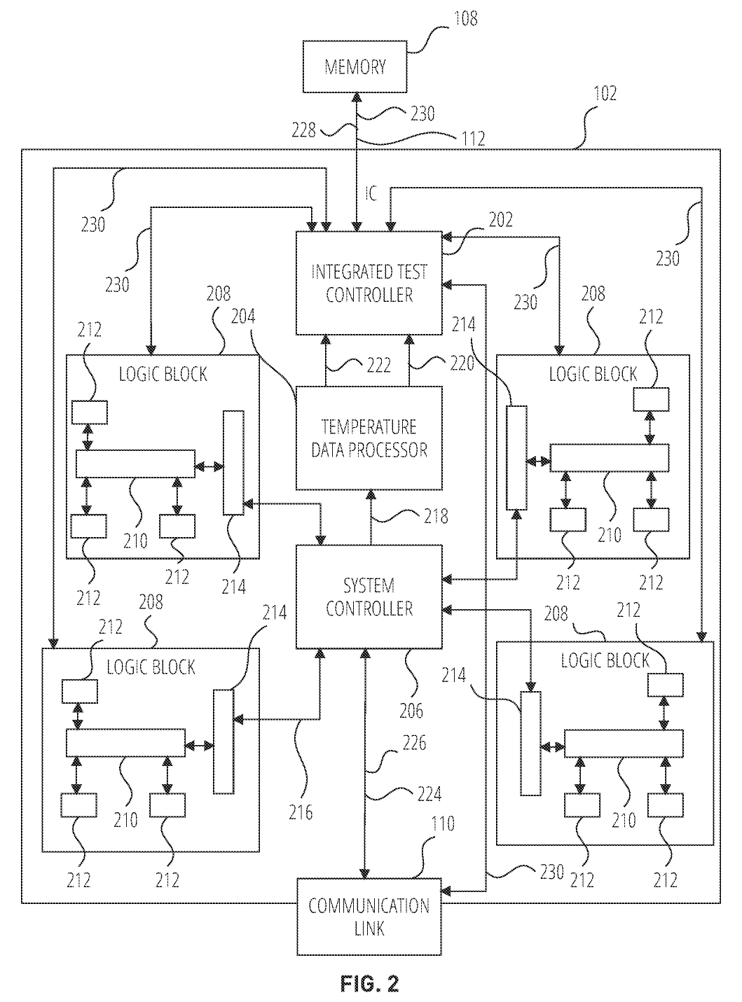

The external test equipment 106 communicates with IC 102 through the communication link 110 to send test patterns and receive test results. The external test equipment 106 and its interaction with the IC 102 in at least one embodiment are described below with reference to FIG. 2.

The memory 108 stores test data, temperature measurements, and analysis results generated during testing operations. This includes detailed temperature statistics such as minimum, maximum, and average values per sensor, which can be used for analyzing test failures and optimizing test patterns.

The system 100 supports various testing scenarios including in-system testing, system level testing, burn-in testing, and automatic test equipment testing, while maintaining temperature monitoring and control capabilities throughout these different testing modes.

FIG. 2 is a detailed block diagram illustrating internal components and interconnections of an IC 102 with temperature monitoring capabilities during structural testing, according to at least one embodiment.

The IC 102 includes multiple logic blocks 208 distributed across the IC die. The logic blocks 208 can include various functional components of the integrated circuit that are exercised during structural testing.

In at least one embodiment, each logic block 208 contains or is associated with a temperature sensing monitor 210, a sensor bridge, and one or more integrated temperature sensors 212 thermally coupled to the logic block 208. Each temperature sensing monitor 210 sequentially monitors the integrated temperature sensors 212 within its corresponding logic block 208. In at least one embodiment, the integrated temperature sensors 212 are located within the logic blocks 208 in proximity to, or within, respective regions of the logic block 208. In at least one embodiment, the integrated temperature sensors 212 are located in proximity to respective regions of the logic block 208 and thermally coupled to the logic blocks 208 without being located within the logic blocks. The integrated temperature sensors 212 can be located and configured to measure the temperature of the associated logic block 208 at multiple distinct locations or regions of the logic block 208. In at least one embodiment, each logic block 208 is associated with a single temperature sensing monitor 210 that sequentially monitors each integrated temperature sensor 212 associated with the logic block 208.

Although the example embodiment shown in FIG. 2 shows exactly one temperature sensing monitor 210 associated with each logic block 208, it will be appreciated that other configurations are possible. In at least one embodiment, a single temperature sensing monitor 210 can be associated with integrated temperature sensors 212 thermally coupled to multiple different logic blocks 208. In at least one embodiment, a single logic block 208 can be associated with more than one temperature sensing monitor 210.

The sensor bridges 214 interface between each temperature sensing monitor 210 and a system controller 206 integrated into the IC die. The sensor bridges 214 enable access to temperature measurements 216 from the integrated temperature sensors 212 during testing operations. In at least one embodiment, the sensor bridge 214 in each logic block 208 interfaces between the corresponding temperature sensing monitor 210 and the system controller 206, with the temperature sensing monitor 210 configured to monitor any one of the associated integrated temperature sensors 212 at a time. After receiving temperature measurements from a sensor, the sensor bridge 214 enables the temperature sensing monitor 210 to activate monitoring of the next sensor in sequence, enabling comprehensive temperature monitoring across all sensors within each logic block.

In at least one embodiment, the system controller 206 processes the temperature measurements 216 received via the sensor bridges 214 to generate temperature data 218 based on the temperature measurements 216. In at least one embodiment, the temperature data 218 combines the temperature measurements 216 from multiple temperature sensing monitors 210. In at least one embodiment, the temperature data 218 processes the temperature measurements 216 from the temperature sensing monitors 210 to generate data in a different format or of a different type from the temperature measurements 216. For example, the temperature measurements 216 can be encoded as raw sensor data, such as a raw temperature code, and the system controller 206 can process this raw sensor data to generate temperature data 218 encoding a Celsius or Fahrenheit temperature value associated with a specific integrated temperature sensor 212 and associated with a time stamp. Various embodiments may use other formats for the temperature measurements 216 and/or temperature data 218.

A temperature data processor 204 integrated into the IC 102 receives or obtains the temperature data 218 from the system controller 206 and processes the temperature data 218 to generate temperature analysis data 222. In at least one embodiment, the temperature analysis data 222 can include information derived from the processing of the temperature data 218, such as minimum, maximum and average temperature values per integrated temperature sensor 212 over a given time period. In at least one embodiment, the temperature analysis data 222 is provided to an integrated test controller 202 integrated into the IC die.

The integrated test controller 202 operates to control the structural testing process. In at least one embodiment, the integrated test controller 202 controls the testing operations based at least in part on testing data 230 or testing instructions received from the external memory 108 via the memory interface 112. In at least one embodiment, the integrated test controller 202 controls the testing operations based at least in part on testing data 230 or testing instructions received from external test equipment 106 received via the communication link 110. Based on the received testing data 230 or testing instructions, the integrated test controller 202 distributes or scans portions of the testing data 230 (such as test patterns of binary data) to the logic blocks 208 as testing data inputs for exercising the logic blocks 208 to perform structural testing. The integrated test controller 202 also captures the testing data outputs generated by the logic blocks 208 based on the received testing data 230. The testing data 230 can include both the testing data inputs scanned into the logic blocks 208 and the testing data outputs captured from the logic blocks 208.

In at least one embodiment, the temperature data processor 204 generates an interrupt signal 220 in response to determining that the temperature data 218 and/or temperature analysis data 222 indicates a predetermined (e.g., critical) temperature event. A critical temperature event can include detection of a temperature from one or more of the integrated temperature sensors 212 that is over a predetermined temperature threshold, or that is over the critical temperature threshold for more than a predetermined period of time. In at least one embodiment, different criteria are applied to different integrated temperature sensors 212 to determine that a critical temperature event has occurred; for example, some logic blocks 208 or some portions of a logic block 208 may be more temperature-sensitive than others, such that the temperature data processor 204 applies a relatively lower critical temperature threshold and/or a relatively shorter predetermined period of time to the temperature measurements associated with that logic block 208 or region in determining that a critical temperature event has occurred. In at least one embodiment, the temperature measurements from multiple integrated temperature sensors 212 are considered in determining that a critical temperature event has occurred.

Based on the temperature analysis data 222 from the temperature data processor 204, the integrated test controller 202 can pause or stop testing operations. In at least one embodiment, the integrated test controller 202 temporarily pauses testing in response to the interrupt signal 220. In at least one embodiment, the integrated test controller 202 halts the testing in response to the interrupt signal 220. In at least one embodiment, the integrated test controller 202 modifies the testing in response to the interrupt signal 220. For example, the integrated test controller 202 can modify the timing and/or content of the testing data 230 sent to the logic blocks 208 in order to mitigate a critical temperature event by reducing the level of switching activity. In at least one embodiment, the integrated test controller 202 can use detailed per-sensor data (such as the temperature analysis data 222) to modify the testing data 230 to reduce the switching rate within a specific logic block 208 or a portion of a logic block 208 monitored by a specific integrated temperature sensor 212.

In at least one embodiment, modifying the timing of the testing data sent to the logic blocks can include reducing a frequency or rate at which test patterns are scanned into the logic blocks 208 and/or a frequency or rate at which testing data outputs are captured out of the logic blocks 208. In at least one embodiment, the rate of testing can be modified to set different rates for different logic blocks 208, such as a lower rate for a logic block associated with high temperature measurements. In at least one embodiment, modifying the content of the testing data can include modifying the bit values of testing data inputs sent to a given logic block, or to a given portion of a logic block, to provide bit values that are more uniform over time, such that the bit value switching rate of testing data inputs to the logic block is reduced. For example, a logic block associated with high temperature measurements can be temporarily provided with uniform bit values, such that the bit values of the testing data inputs for that logic block are frozen at their current values for a period of time to temporarily lower the switching rate of the logic block and permit the logic block to cool down.

In at least one embodiment, the temperature data processor 204 deactivates the interrupt signal 220 to resume testing after a temporary pause based on one or more deactivation criteria. For example, the temperature data processor 204 may only deactivate the interrupt signal 220 when two conditions are satisfied: first, the integrated temperature sensor 212 that originally triggered the critical temperature event provides a temperature value that has transgressed the predetermined temperature threshold, and second, no other integrated temperature sensor 212 has triggered a critical temperature event during this cooling period. This dual-condition approach can help to ensure that the integrated test controller 202 does not resume testing until all or a threshold number of temperature measurements 216 across the monitored sensors indicate safe operating conditions.

In at least one embodiment, the integrated test controller 202 also generates temperature log data 228 based on the temperature analysis data 222. The temperature log data 228 can be stored in memory 108 via the memory interface 112. In at least one embodiment, the temperature log data 228 includes information such as test pause events, test halt events, critical temperature events, durations of events, locations of events, testing cycle counts, temperature-induced modifications of testing operations, and other forms of information. In at least one embodiment, the temperature log data 228 includes some or all of the temperature analysis data 222.

In at least one embodiment, the temperature log data 228 includes debugging data generated in association with a critical temperature event triggering the interrupt signal 220. For example, during a test pause event triggered by the interrupt signal 220, the integrated test controller 202 can record debugging data such as: the number of times the test is paused, the duration of each pause event, and the testing cycle count at which each pause occurs. This detailed logging can help to enable analysis to make future changes in test patterns to reduce high temperature events.

In at least one embodiment, a communication link 110 interfaces with the system controller 206 to provide external test equipment data 224 and/or coolant control data 226 to external systems. As described above, the communication link 110 can support one or more standard interfaces, such as PCIe or I²C. The external test equipment data 224 and/or coolant control data 226 can be stored in registers of the communication link 110 for access by the external test equipment 106 and/or coolant system 104 (shown in FIG. 1).

In at least one embodiment, the external test equipment 106 interfaces with the IC 102 through the communication link 110 to send test patterns and receive test results, such as testing data 230, during structural testing. The external test equipment 106 can receive external test equipment data 224 formatted for access through the communication link 110. In at least one embodiment, the external test equipment data 224 is based on the temperature measurements 216. In at least one embodiment, during burn-in testing, the external test equipment 106 functions as a burn-in tester that sends TEST-IN test patterns to the IC 102 as the DUT and receives TEST-OUT logic output results, while coordinating with the burn-in coolant system 104. The external test equipment 106 can utilize the more detailed and accurate internal temperature sensor data provided through the communication link to better control testing operations, compared to prior approaches that relied on limited external temperature sensors.

In at least one embodiment, the coolant system 104 receives the coolant control data 226 from the IC 102 through the communication link 110 to regulate temperature during testing operations. Unlike prior approaches that relied on external temperature diode sensors coupled externally to the periphery of an IC chip, providing limited temperature monitoring coverage, the coolant system 104 can receive detailed and distributed temperature feedback data from multiple internal temperature sensors distributed throughout the IC's logic blocks. During burn-in testing, the coolant system 104 can function as a burn-in coolant that receives temperature feedback through the communication link 110 to provide active cooling based on the internal temperature measurements. The coolant system 104 enables dynamic and timely adjustment of cooling parameters based on detailed temperature data, helping prevent thermal runaway issues that could damage testing equipment or the IC 102 itself. In at least one embodiment, the coolant system 104 can adjust cooling to specific logic blocks 208 or portions of logic blocks 208 based on localized temperature measurements. In at least one embodiment, the coolant system 104 can adjust cooling in real-time with greater responsiveness than prior approaches due to the faster temperature feedback enabled by the use of integrated temperature sensors 212 thermally coupled to regions of the logic blocks 208 internally within the PIC die.

In at least one embodiment, the components of the IC 102 that process data, such as the temperature sensing monitors 210, sensor bridges 214, system controller 206, temperature data processor 204, and integrated test controller 202 are or include digital circuits that process digital data and/or digital signals. The data and signals shown in FIG. 2, such as temperature measurements 216, temperature data 218, interrupt signal 220, temperature analysis data 222, external test equipment data 224, coolant control data 226, temperature log data 228, and testing data 230 can be digital data or digital signals.

The interconnected temperature monitoring, data processing, and communication components of the IC 102 shown in FIG. 2 are active and accessible during structural testing. This can enable comprehensive temperature monitoring during various structural testing scenarios, including in-system testing, system level testing, burn-in testing, and/or automatic test equipment testing.

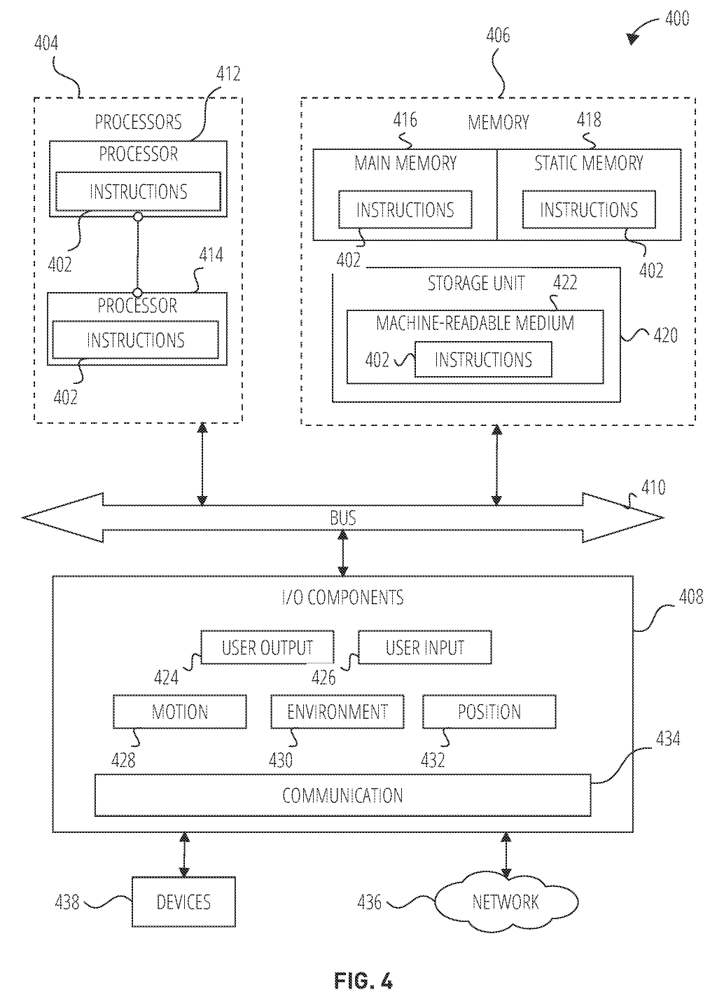

In at least one embodiment, one or more of the external components, including the memory 108, coolant system 104, and/or external test equipment 106, can be implemented using one or more components of a machine or system such as the machine 400 described below with reference to FIG. 4.

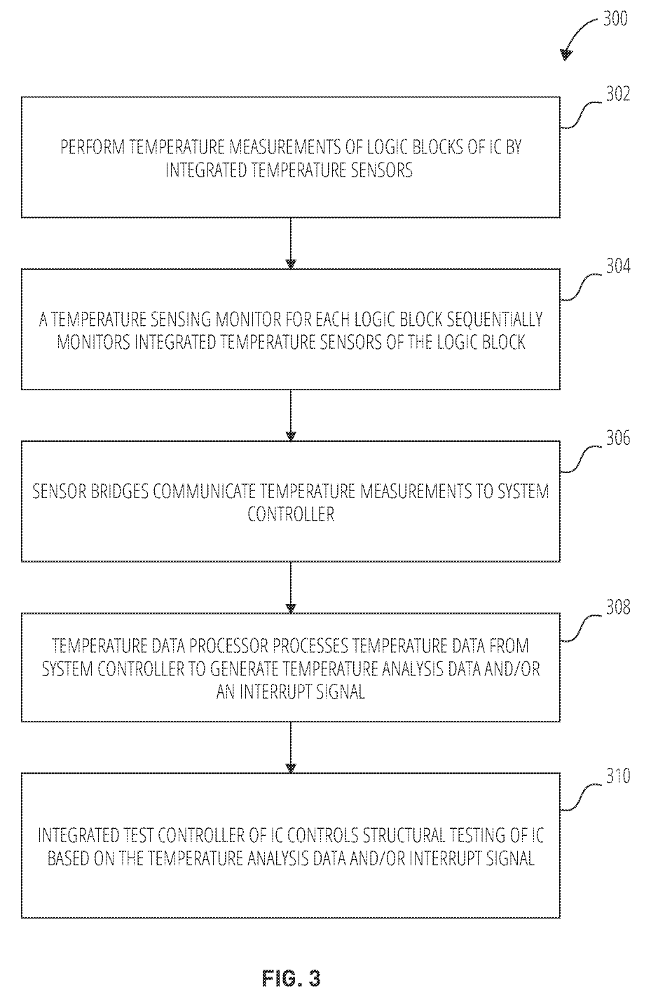

FIG. 3 is a flow diagram illustrating operations of a method 300 for monitoring and controlling temperature during structural testing of an integrated circuit, according to at least one embodiment.

At operation 302, integrated temperature sensors perform temperature measurements of logic blocks within an integrated circuit (IC) during a structural testing operation. These sensors can include bipolar junction transistor (BJT)-based sensors, diode-based sensors, or ring oscillator-based sensors distributed across various logic blocks. In at least one embodiment, the sensors are integrated temperature sensors 212 thermally coupled to logic blocks 208 of the IC 102.

At operation 304, a temperature sensing monitor for each logic block sequentially monitors the integrated temperature sensors within that logic block. In at least one embodiment, each temperature sensing monitor 210 cycles through its associated integrated temperature sensors 212, collecting temperature measurements 216 from one sensor at a time.

At operation 306, sensor bridges communicate temperature measurements to a system controller. In at least one embodiment, the sensor bridges 214 interface between the temperature sensing monitors 210 and the system controller 206, enabling access to the temperature measurements 216 from the integrated temperature sensors 212 during testing operations. In at least one embodiment, the system controller 206 converts the raw temperature codes of the temperature measurements 216 from the integrated temperature sensors 212 into temperature values (such as Fahrenheit or Celsius values) encoded as temperature data 218.

At operation 308, a temperature data processor processes temperature data from the system controller to generate temperature analysis data and/or an interrupt signal. In at least one embodiment, the processing at operation 308 includes computing minimum, maximum, and/or average temperatures for each integrated temperature sensor 212 sensors within each logic block 208. In at least one embodiment, one or more statistics, such as a minimum, a maximum, an average, and/or a weighted average temperature value, are computed across multiple of the integrated temperature sensors 212 to provide aggregated measurements of temperature. In at least one embodiment, the processing at operation 308 includes determination of a predetermined temperature event based on the temperature data from the system controller, and generates an interrupt signal 220 based on determination of the predetermined temperature event.

At operation 310, an integrated test controller of the IC controls the structural testing based on the temperature analysis data and/or the interrupt signal. In at least one embodiment, the integrated test controller 202 can implement various control responses, including temporarily pausing testing until temperature decreases, stopping testing entirely, and/or modifying test execution parameters. In at least one embodiment, the integrated test controller 202 also generates temperature log data 228 based on the temperature analysis data 222 that captures detailed temperature measurements and testing events.

It will be appreciated that the functionality of the IC 102 components described herein is not limited to the operations shown in FIG. 3, but can also include storing the temperature log data 228 to the memory 108, scanning and capturing the testing data 230 to exercise the logic blocks 208, communicating with the coolant system 104 and/or external test equipment 106, and other operations and functions described herein.

### Machine Architecture

FIG. 4 is a diagrammatic representation of a machine 400 within which instructions 402 (e.g., software, a program, an application, an applet, an app, or other executable code) for causing the machine 400 to perform one or more operations, according to at least one embodiment. The instructions 402 transform the general, non-programmed machine 400 into a particular machine 400 programmed to carry out the described and illustrated functions in the manner described. The machine 400 can operate as a standalone device or can be coupled (e.g., networked) to other machines. In a networked deployment, the machine 400 can operate in the capacity of a server machine or a client machine in a server-client network environment, or as a peer machine in a peer-to-peer (or distributed) network environment. The machine 400 can comprise, but not be limited to, a server computer, a client computer, a personal computer (PC), a tablet computer, a laptop computer, a netbook, a set-top box (STB), a personal digital assistant (PDA), an entertainment media system, a cellular telephone, a smartphone, a mobile device, a wearable device (e.g., a smartwatch, a pair of augmented reality glasses), a smart home device (e.g., a smart appliance), other smart devices, a web appliance, a network router, a network switch, a network bridge, or any machine capable of executing the instructions 402, sequentially or otherwise, that specify actions to be taken by the machine 400. Further, while a single machine 400 is illustrated, in at least one embodiment a machine can include a collection or system of machines that individually or jointly execute the instructions 402 to perform any one or more operations of any one or more of the methodologies described herein. In some examples, the machine 400 can comprise both client and server systems, with certain operations of a particular method or algorithm being performed on the server-side and with certain operations of the particular method or algorithm being performed on the client-side.

The machine 400 can include processors 404, memory 406, and input/output I/O components 408, which can be configured to communicate with each other via a bus 410. In an example, the processors 404 (e.g., a Central Processing Unit (CPU), a Reduced Instruction Set Computing (RISC) Processor, a Complex Instruction Set Computing (CISC) Processor, a Graphics Processing Unit (GPU), a Digital Signal Processor (DSP), an Application Specific Integrated Circuit (ASIC), a Radio-Frequency Integrated Circuit (RFIC), another processor, or any suitable combination thereof) can include, for example, a processor 412 and a processor 414 that execute the instructions 402. The processors 404 can be a multi-core processor that can comprise two or more independent processors (sometimes referred to as “cores”) that can execute instructions contemporaneously. Although FIG. 4 shows multiple processors 404, the machine 400 can include a single processor with a single-core, a single processor with multiple cores (e.g., a multi-core processor), multiple processors with a single core, multiple processors with multiples cores, or any combination thereof.

The memory 406 can include a main memory 416, a static memory 418, and/or a storage unit 420, all accessible to the processors 404 via the bus 410. The main memory 406, the static memory 418, and the storage unit 420 store the instructions 402 embodying any one or more of the methodologies or functions described herein. The instructions 402 can also reside, completely or partially, within the main memory 416, within the static memory 418, within machine-readable medium 422 within the storage unit 420, within at least one of the processors 404 (e.g., within the processor’s cache memory), or any suitable combination thereof, during execution thereof by the machine 400.

The I/O components 408 can include a wide variety of components to receive input, provide output, produce output, transmit information, exchange information, capture measurements, and so on. The specific I/O components 408 that are included in a particular machine will depend on the type of machine. For example, portable machines such as mobile phones can include a touch input device or other such input mechanisms, while a headless server machine will likely not include such a touch input device. It will be appreciated that the I/O components 408 can include many other components that are not shown in FIG. 4. In various examples, the I/O components 408 can include user output components 424 and user input components 426. The user output components 424 can include or communicate with visual components (e.g., one or more displays such as a plasma display panel (PDP), a light-emitting diode (LED) display, a liquid crystal display (LCD), a projector, or a cathode ray tube (CRT) display), acoustic components (e.g., speakers), haptic components (e.g., a vibratory motor, resistance mechanisms), other signal generators, and so forth. The user input components 426 can include alphanumeric input components (e.g., a keyboard, a touch screen configured to receive alphanumeric input, a photo-optical keyboard, or other alphanumeric input components), point-based input components (e.g., a mouse, a touchpad, a trackball, a joystick, a motion sensor, or another pointing instrument), tactile input components (e.g., a physical button, a touch screen that provides location and force of touches or touch gestures, or other tactile input components), audio input components (e.g., a microphone), and the like.

In further examples, the I/O components 408 can include motion components 428, environmental components 430, or position components 432, among a wide array of other components.

The motion components 428 can include acceleration sensor components (e.g., accelerometer), gravitation sensor components, rotation sensor components (e.g., gyroscope).

The environmental components 430 can include, for example, one or more externally-facing cameras (with still image/photograph and video capabilities), illumination sensor components (e.g., photometer or ambient light sensor), temperature sensor components (e.g., one or more thermometers that detect ambient temperature), humidity sensor components, pressure sensor components (e.g., barometer), acoustic sensor components (e.g., one or more microphones that detect background noise), proximity sensor components (e.g., infrared sensors that detect nearby objects), gas sensors (e.g., gas detection sensors to detection concentrations of hazardous gases for safety or to measure pollutants in the atmosphere), depth sensors (such as one or more LIDAR arrays), or other components that can provide indications, measurements, or signals corresponding to a surrounding physical environment.

The position components 432 include location sensor components (e.g., a GPS receiver component), altitude sensor components (e.g., altimeters or barometers that detect air pressure from which altitude may be derived), orientation sensor components (e.g., magnetometers), and the like.

Communication may be implemented using a wide variety of technologies. The I/O components 408 further include communication components 434 operable to couple the machine 400 to a network 436 or devices 438 via respective coupling or connections. For example, the communication components 434 can include a network interface component or another suitable device to interface with the network 436. In further examples, the communication components 434 can include wired communication components, wireless communication components, cellular communication components, Near Field Communication (NFC) components, Bluetooth® components (e.g., Bluetooth® Low Energy), Wi-Fi® components, and other communication components to provide communication via other modalities. The devices 438 can be another machine or any of a wide variety of peripheral devices (e.g., a peripheral device coupled via a USB).

Moreover, the communication components 434 can detect identifiers or include components operable to detect identifiers. For example, the communication components 434 can include Radio Frequency Identification (RFID) tag reader components, NFC smart tag detection components, optical reader components (e.g., an optical sensor to detect one-dimensional bar codes such as Universal Product Code (UPC) bar code, multi-dimensional bar codes such as Quick Response (QR) code, Aztec code, Data Matrix, DataglyphTM, MaxiCode, PDF417, Ultra Code, UCC RSS-2D bar code, and other optical codes), or acoustic detection components (e.g., microphones to identify tagged audio signals). In addition, a variety of information can be derived via the communication components 434, such as location via Internet Protocol (IP) geolocation, location via Wi-Fi® signal triangulation, location via detecting an NFC beacon signal that can indicate a particular location, and so forth.

The various memories can store one or more sets of instructions and data structures (e.g., software) embodying or used by any one or more of the methodologies or functions described herein. These instructions (e.g., the instructions 402), when executed by processors 404, can cause various operations to implement one or more components or operations of disclosed examples.

The instructions 402 can be transmitted or received over the network 436, using a transmission medium, via a network interface device (e.g., a network interface component included in the communication components 434) and using any one of several well-known transfer protocols (e.g., hypertext transfer protocol (HTTP)). Similarly, the instructions 402 can be transmitted or received using a transmission medium via a coupling (e.g., a peer-to-peer coupling) to the devices 438.

### Examples

Specific example embodiments are now described. In view of the above-described implementations of subject matter this application discloses the following list of examples, wherein one feature of an example in isolation or more than one feature of an example, taken in combination and, optionally, in combination with one or more features of one or more further examples are further examples also falling within the disclosure of this application.

Example 1 is an integrated circuit comprising: a plurality of logic blocks; a plurality of integrated temperature sensors thermally coupled to the plurality of logic blocks; and an integrated test controller to control structural testing of the integrated circuit based on temperature measurements performed by the plurality of integrated temperature sensors.

In Example 2, the subject matter of Example 1 includes, wherein: the control of the structural testing comprises at least one of: temporarily pausing the structural testing; or ending the structural testing.

In Example 3, the subject matter of Examples 1–2 includes, wherein: the control of the structural testing comprises modifying at least one of: timing of structural testing data inputs to logic blocks of the integrated circuit; or data values of the structural testing data inputs to the logic blocks of the integrated circuit.

In Example 4, the subject matter of Examples 1–3 includes, wherein: the integrated test controller: generates temperature log data based on the temperature measurements; and provides the temperature log data to a memory external to the integrated circuit.

In Example 5, the subject matter of Examples 1–4 includes, a communication link to provide coolant control data to a coolant system, the coolant control data being based on the temperature measurements.

In Example 6, the subject matter of Example 5 includes, wherein: the communication link provides external test equipment data to external test equipment, the external test equipment data being based on the temperature measurements.

In Example 7, the subject matter of Example 6 includes, a plurality of temperature sensing monitors, each temperature sensing monitor being coupled to a corresponding one or more integrated temperature sensors of the plurality of integrated temperature sensors to sequentially monitor the temperature measurements from each corresponding integrated temperature sensor.

In Example 8, the subject matter of Example 7 includes, wherein: a first plurality of integrated temperature sensors of the plurality of integrated temperature sensors is coupled to a first logic block of the plurality of logic blocks and corresponds to a first temperature sensing monitor of the plurality of temperature sensing monitors; and a second plurality of integrated temperature sensors of the plurality of integrated temperature sensors is coupled to a second logic block of the plurality of logic blocks and corresponds to a second temperature sensing monitor of the plurality of temperature sensing monitors.

In Example 9, the subject matter of Example 8 includes, a system controller to: receive the temperature measurements from the plurality of temperature sensing monitors; and process the temperature measurements to generate the coolant control data and the external test equipment data.

In Example 10, the subject matter of Example 9 includes, a plurality of sensor bridges, each sensor bridge providing a communication interface between the system controller and a corresponding temperature sensing monitor of the plurality of temperature sensing monitors.

In Example 11, the subject matter of Examples 9–10 includes, wherein: the system controller generates temperature data based on the temperature measurements; and the integrated circuit further comprises a temperature data processor to process the temperature data to cause the integrated test controller to control the structural testing.

In Example 12, the subject matter of Example 11 includes, wherein: the temperature data processor causing the integrated test controller to control the structural testing comprises: the temperature data processor generating an interrupt signal based on the temperature data; and the integrated test controller temporarily pausing or ending the structural testing in response to the interrupt signal.

In Example 13, the subject matter of Examples 11–12 includes, wherein: the temperature data processor generates temperature analysis data based on the temperature data; and the integrated test controller: generates temperature log data based on the temperature analysis data; and provides the temperature log data to a memory external to the integrated circuit.

In Example 14, the subject matter of Examples 1–13 includes, wherein: the plurality of integrated temperature sensors comprises at least one of: bipolar junction transistor (BJT)-based temperature sensors; diode-based temperature sensors; or ring oscillator-based temperature sensors.

Example 15 is a system comprising: an integrated circuit comprising: a plurality of logic blocks; a plurality of integrated temperature sensors distributed across the plurality of logic blocks; and an integrated test controller to control structural testing of the integrated circuit based on temperature measurements performed by the plurality of integrated temperature sensors.

In Example 16, the subject matter of Example 15 includes, wherein: the system further comprises a coolant system; and the integrated circuit further comprises a communication link to provide coolant control data to the coolant system, the coolant control data being based on the temperature measurements.

In Example 17, the subject matter of Example 16 includes, wherein: the system further comprises external test equipment; and the communication link provides external test equipment data to the external test equipment, the external test equipment data being based on the temperature measurements.

In Example 18, the subject matter of Examples 15–17 includes, wherein: the system further comprises a memory external to the integrated circuit; and the integrated test controller: generates temperature log data based on the temperature measurements; and provides the temperature log data to the memory.

Example 19 is a method for performing structural testing of an integrated circuit, the method comprising: performing temperature measurements of a plurality of logic blocks of the integrated circuit by a plurality of integrated temperature sensors of the integrated circuit thermally coupled to the plurality of logic blocks; and controlling, by an integrated test controller of the integrated circuit, the structural testing based on the temperature measurements.

In Example 20, the subject matter of Example 19 includes, wherein: the controlling of the structural testing comprises at least one of: temporarily pausing the structural testing; or ending the structural testing.

Example 21 is at least one machine-readable medium including instructions that, when executed by processing circuitry, cause the processing circuitry to perform operations to implement of any of Examples 1–20.

Example 22 is an apparatus comprising means to implement of any of Examples 1–20.

Example 23 is a system to implement of any of Examples 1–20.

Example 24 is a method to implement of any of Examples 1–20.

Other technical features may be readily apparent to one skilled in the art from the figures, descriptions, and claims.

What is claimed is:

1. An integrated circuit comprising:
a plurality of logic blocks;
a plurality of integrated temperature sensors thermally coupled to the plurality of logic blocks; and
an integrated test controller to control structural testing of the integrated circuit based on temperature measurements performed by the plurality of integrated temperature sensors.

2. The integrated circuit of claim 1, wherein:
the control of the structural testing comprises at least one of:
temporarily pausing the structural testing; or
ending the structural testing.

3. The integrated circuit of claim 1, wherein:
the control of the structural testing comprises modifying at least one of:
timing of structural testing data inputs to logic blocks of the integrated circuit; or
data values of the structural testing data inputs to the logic blocks of the integrated circuit.

4. The integrated circuit of claim 1, wherein:
the integrated test controller:
generates temperature log data based on the temperature measurements; and
provides the temperature log data to a memory external to the integrated circuit.

5. The integrated circuit of claim 1, further comprising:
a communication link to provide coolant control data to a coolant system, the coolant control data being based on the temperature measurements.

6. The integrated circuit of claim 5, wherein:
the communication link provides external test equipment data to external test equipment, the external test equipment data being based on the temperature measurements.

7. The integrated circuit of claim 6, further comprising:
a plurality of temperature sensing monitors, each temperature sensing monitor being coupled to a corresponding one or more integrated temperature sensors of the plurality of integrated temperature sensors to sequentially monitor the temperature measurements from each corresponding integrated temperature sensor.

8. The integrated circuit of claim 7, wherein:
a first plurality of integrated temperature sensors of the plurality of integrated temperature sensors is coupled to a first logic block of the plurality of logic blocks and corresponds to a first temperature sensing monitor of the plurality of temperature sensing monitors; and
a second plurality of integrated temperature sensors of the plurality of integrated temperature sensors is coupled to a second logic block of the plurality of logic blocks and corresponds to a second temperature sensing monitor of the plurality of temperature sensing monitors.

9. The integrated circuit of claim 8, further comprising:
a system controller to:
receive the temperature measurements from the plurality of temperature sensing monitors; and
process the temperature measurements to generate the coolant control data and the external test equipment data.

10. The integrated circuit of claim 9, further comprising:
a plurality of sensor bridges, each sensor bridge providing a communication interface between the system controller and a corresponding temperature sensing monitor of the plurality of temperature sensing monitors.

11. The integrated circuit of claim 9, wherein:
the system controller generates temperature data based on the temperature measurements; and
the integrated circuit further comprises a temperature data processor to process the temperature data to cause the integrated test controller to control the structural testing.

12. The integrated circuit of claim 11, wherein:
the temperature data processor causing the integrated test controller to control the structural testing comprises:
the temperature data processor generating an interrupt signal based on the temperature data; and
the integrated test controller temporarily pausing or ending the structural testing in response to the interrupt signal.

13. The integrated circuit of claim 11, wherein:
the temperature data processor generates temperature analysis data based on the temperature data; and
the integrated test controller:
generates temperature log data based on the temperature analysis data; and
provides the temperature log data to a memory external to the integrated circuit.

14. The integrated circuit of claim 1, wherein:
the plurality of integrated temperature sensors comprises at least one of:
bipolar junction transistor (BJT)-based temperature sensors;
diode-based temperature sensors; or
ring oscillator-based temperature sensors.

15. A system comprising:
an integrated circuit comprising:
a plurality of logic blocks;
a plurality of integrated temperature sensors distributed across the plurality of logic blocks; and
an integrated test controller to control structural testing of the integrated circuit based on temperature measurements performed by the plurality of integrated temperature sensors.

16. The system of claim 15, wherein:
the system further comprises a coolant system; and
the integrated circuit further comprises a communication link to provide coolant control data to the coolant system, the coolant control data being based on the temperature measurements.

17. The system of claim 16, wherein:
the system further comprises external test equipment; and
the communication link provides external test equipment data to the external test equipment, the external test equipment data being based on the temperature measurements.

18. The system of claim 15, wherein:
the system further comprises a memory external to the integrated circuit; and
the integrated test controller:
generates temperature log data based on the temperature measurements; and
provides the temperature log data to the memory.

19. A method for performing structural testing of an integrated circuit, the method comprising:
performing temperature measurements of a plurality of logic blocks of the integrated circuit by a plurality of integrated temperature sensors of the integrated circuit thermally coupled to the plurality of logic blocks; and
controlling, by an integrated test controller of the integrated circuit, the structural testing based on the temperature measurements.

20. The method of claim 19, wherein:
the controlling of the structural testing comprises at least one of:
temporarily pausing the structural testing; or
ending the structural testing.
